(19) United States
(12) Patent Application Publication
(10) Pub. No.: US 2024/0255439 A1
(43) Pub. Date: Aug. 1, 2024

(54) DEFECT DETECTION DEVICE AND DEFECT DETECTION METHOD

(71) Applicant: Samsung Electronics Co., Ltd., Suwon-si (KR)

(72) Inventors: Heeyoon Han, Suwon-si (KR); Donghoon Kim, Suwon-si (KR); Sungyoon Ryu, Suwon-si (KR); Younghoon Sohn, Suwon-si (KR); Sunhong Jun, Suwon-si (KR)

(73) Assignee: Samsung Electronics Co., Ltd., Suwon-si (KR)

(21) Appl. No.: 18/367,784

(22) Filed: Sep. 13, 2023

(30) Foreign Application Priority Data
Jan. 27, 2023 (KR) 10-2023-0011110

(51) Int. Cl. G01N 21/95; G01N 21/31; G06N 20/00

(52) U.S. Cl. CPC G01N 21/9501; G01N 21/31; G06N 20/00

(57) ABSTRACT

A defect detection method includes radiating light onto a substrate, obtaining a spectrum image, performing an electrical die sorting (EDS) test on the substrate, inspecting defects of each of a plurality of blocks of the substrate based on a result of the EDS test, generating a defect map, generating spectrum image information by matching the spectrum image with the defect map, training a defect detection model by using the defect grade as an output value and the spectrum image information as an input value, obtaining a target spectrum image with respect to a target substrate, extracting a feature vector from the target spectrum image by using the defect detection model, and detecting a target defect grade of the target spectrum image based on the feature vector, and generating a target defect map based on the target defect grade.

### CROSS-REFERENCE TO RELATED APPLICATION

This application is based on and claims priority under 35 U.S.C. § 119 to Korean Patent Application No. 10-2023-0011110, filed on Jan. 27, 2023, in the Korean Intellectual Property Office, the disclosure of which is incorporated by reference herein in its entirety.

### BACKGROUND

The inventive concept relates to a defect detection device and a defect detection method.

The core of a semiconductor process is a technology of drawing circuit patterns on a silicon wafer. As a degree of integration of the semiconductor process increases and a line width becomes finer, types and amounts of defects tend to increase exponentially. For this reason, techniques of detecting and predicting defects of semiconductor devices have been studied. These techniques include a technique of predicting defects of a pattern by using a spectrum image of the pattern transferred to a substrate.

### SUMMARY

Aspects of the inventive concept provide a defect detection device and a defect detection method capable of predicting defects for a plurality of blocks in a substrate based on a spectrum image.

In addition, issues addressed by the inventive concept is not limited to the above-mentioned issues, and other issues may be clearly understood by those of ordinary skill in the art from the description below.

According to an aspect of the inventive concept, there is provided a defect detection method including radiating light onto a substrate, obtaining a spectrum image indicating an amount of the light according to a wavelength from reflected light reflected from the substrate, performing an electrical die sorting (EDS) test on the substrate, inspecting defects of each of a plurality of blocks of the substrate based on a result of the EDS test, generating a defect map indicating a defect grade of each of the plurality of blocks based on the defects, generating spectrum image information including the spectrum image and defect information corresponding to the spectrum image by matching the spectrum image with the defect map, training a defect detection model by using the defect grade as an output value and the spectrum image information as an input value, obtaining a target spectrum image with respect to a target substrate, extracting a feature vector from the target spectrum image by using the defect detection model, and detecting a target defect grade of the target spectrum image based on the feature vector, and generating a target defect map based on the target defect grade

According to another aspect of the inventive concept, there is provided a defect detection device including an optical device configured to radiate light onto a substrate and obtain a plurality of spectrum images of each of a plurality of blocks in the substrate, a defect inspection unit configured to perform an EDS test on the substrate and inspect defects of each of the plurality of blocks of the substrate based on a result of the EDS test, a matching unit configured to match the plurality of spectrum images with defect information of each of the plurality of blocks, a database storing the plurality of matched spectrum images and the defect information corresponding to the plurality of spectrum images, a model learning unit configured to train a defect detection model by using a defect grade as an output value and the plurality of spectrum images and the defect information received from the database as input values, and a defect detection unit configured to extract a feature vector from a target spectrum image obtained from the optical device by using the defect detection model and detect a target defect grade of the target spectrum image based on the feature vector.

According to another aspect of the inventive concept, there is provided a defect detection method including radiating light onto a substrate, generating a spectrum image in units of any one or more of a whole substrate, a shot, a chip, and a block from reflected light reflected from the substrate, extracting a spectrum image of each of a plurality of blocks based on chip layout information of the substrate and location information of each of the plurality of blocks of the substrate, performing an EDS test on the substrate, inspecting defects of each of the plurality of blocks of the substrate based on a result of the EDS test, generating a defect map indicating a defect grade of each of the plurality of blocks based on the defects, generating spectrum image information including the spectrum image and defect information corresponding to the spectrum image by matching the spectrum image with the defect map, training a defect detection model by using the defect grade as an output value and the spectrum image information as an input value, obtaining a target spectrum image from an optical device, extracting a feature vector from the target spectrum image by using the defect detection model, and detecting a target defect grade of the target spectrum image based on the feature vector, and generating a target defect map based on the target defect grade, wherein the inspecting of the defects includes classifying types of the defects of each of the plurality of blocks of the substrate based on a result of the EDS test and selecting a target defect that is an inspection target based on the classified types of the defects.

### BRIEF DESCRIPTION OF THE DRAWINGS

Embodiments will be more clearly understood from the following detailed description taken in conjunction with the accompanying drawings in which:

FIG. 1 is a block diagram illustrating a defect detection device according to an embodiment;

FIG. 2 is a schematic configuration diagram illustrating an optical device used in a defect detection method according to an embodiment;

FIGS. 3 and 4 are diagrams illustrating a measurement area on a substrate by the optical device of FIG. 2, according to an embodiment;

FIG. 5 is a block diagram illustrating a defect detection device according to an embodiment;

FIG. 6 is a flowchart illustrating a defect detection method according to an embodiment;

FIGS. 7 and 8 are defect maps illustrating a defect detection method, according to an embodiment; and

FIG. 9 is a graph illustrating effects of a defect detection device and a defect detection method, according to an embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted.

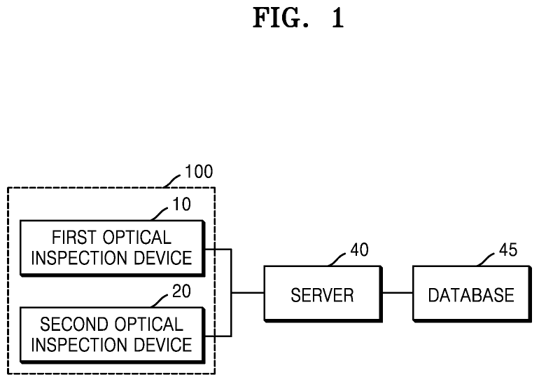

FIG. 1 is a block diagram illustrating a defect detection device according to an embodiment.

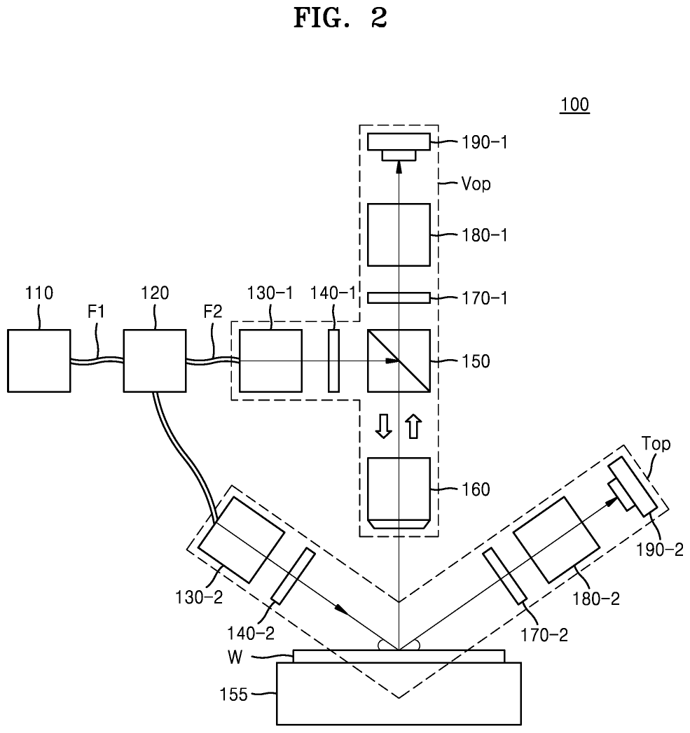

Referring to FIG. 1, a defect detection device 1 may include an optical device 100, a server 40 and a database 45. The optical device 100 may include a first optical inspection device 10 and a second optical inspection device 20. The first optical inspection device 10 may include or may be a vertical optical system Vop, and the second optical inspection device 20 may include or may be a tilt optical system Top. The optical device 100 may be a device based on a spectral microscopic inspection (SMI). For example, the optical device 100 may be a spectral microscopic inspection (SMI) device. The optical device 100 is specifically described in FIG. 2. The optical device 100 may transmit spectrum data obtained by inspecting a substrate to the server 40.

The server 40 may receive the spectrum data from the optical device 100 and store the spectrum data in the database 45. The server 40 may include various integrated circuit components capable of performing various functions under the control of one or more microprocessors and/or another control device, and software elements, such as memory elements, processing elements, logic elements, lookup elements.

The software elements of the server 40 may be implemented in any programming or scripting language such as C, C++, C#, Java, JavaScript, JavaScript Object Notation (JSON), VBScript, Macromedia Cold Fusion, COBOL, Active server pages, Perl, assembly, PHP, awk, Python, Visual Basic, SQL storage procedures, PL/SQL, any Unix shell script, and/or extensible markup language (XML). Various algorithms may be implemented in any combination of data structures, objects, processes, routines, or other programming elements. The server 40 may perform various calculations by using the spectrum data.

FIG. 2 is a schematic structural diagram of an inspection device based on an SMI according to an embodiment.

Referring to FIG. 2, the inspection device 100 based on the SMI according to the present embodiment may be an inspection device based on imaging ellipsometry (IE). For example, the SMI device may be an IE device. Here, the IE may include or may be spectroscopic imaging ellipsometry (SIE). Ellipsometry is a method of measuring an optical microstructure of a single-layer thin film or a multi-layer thin film on a sample by analyzing a polarization state that changes when an incident light is reflected from the sample, and may not need a specific measurement condition such as vacuum because the reflection of light is used.

On the other hand, spectroscopic ellipsometry having a spectroscopic function measures and analyzes an inspection target based on a large amount of information measured at various wavelengths, and thus, reliability of analysis may be improved. A method of measuring and analyzing an inspection target by obtaining a two-dimensional (2D) image through a detector such as a charge-coupled device (CCD) camera based on ellipsometry or spectroscopic ellipsometry may be the IE or the SIE. For example, the IE or SIE may include a two-dimensional (2D) image detector such as a charge-coupled device (CCD) camera.

On the other hand, in the inspection device 100 based on the SMI of the present embodiment, SMI stands for Spectral Microscopic Inspection, and is a combination word that combines spectral related to spectroscopic, microscopic related to image, and inspection related to the SIE mentioned above. Hereinafter, the ‘the inspection device based on the SMI or SMI device’ is simply referred to as the ‘inspection device’.

The inspection device 100 of the present embodiment may include the vertical optical system Vop, the tilt optical system Top, and a stage 155. In FIG. 2, the vertical optical system Vop and the tilt optical system Top are distinguished and expressed by dotted lines, and may share a light source 110 and a monochromator 120. Accordingly, the light source 110 and the monochromator 120 are not distinguished by dotted lines. For example, the vertical optical system Vop may include the light source 110, the monochromator 120, a first collimator 130-1, a first polarizer 140-1, a beam splitter 150, an objective lens 160, a first analyzer 170-1, a first imaging lens unit 180-1, and a first detector 190-1.

On the other hand, in an optical inspection device, an optical system includes an illumination optical system and an imaging optical system. Generally, the illumination optical system may mean an optical system on a path from the light source 110 to a substrate W, and the imaging optical system may mean an optical system on a path from the substrate W to a detector.

For example, in the vertical optical system Vop, the illumination optical system may include the first collimator 130-1, the first polarizer 140-1, and the beam splitter 150, and the imaging optical system may include the objective lens 160, the first analyzer 170-1, and the first imaging lens unit 180-1. In addition, in the tilt optical system Top, the illumination optical system may include a second collimator 130-2 and a second polarizer 140-2, and the imaging optical system may include a second analyzer 170-2 and a second imaging lens unit 180-2. For example, the first lens unit 180-1 may be a lens and the second lens unit 180-2 may be a lens.

The light source 110 may be a broadband light source or a multi-wavelength light source that generates and outputs a broadband light. The broadband light of the light source 110 may be a multi-color light including light of a plurality of wavelength bands. For example, in the inspection device 100 of the present embodiment, the light source 110 may generate and output light in a wavelength range of about 150 nm to about 2100 nm. The wavelength range of the light generated by the light source 110 is not limited to the above range. The light source 110 may be a halogen lamp light source that produces a continuous spectrum of light or a light emitting diode (LED) light source. However, the type of the light source 110 is not limited thereto. In the inspection device 100 of the present embodiment, the light source 110 is implemented as a broadband light source, and thus, various spectrums may be configured.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The monochromator 120 may convert the broadband light of the light source 110 into a monochromatic light and output the monochromatic light. Here, the monochromatic light may refer to light having a very short wavelength range. For example, the monochromatic light may be light having a wavelength width/variant of about several nanometers. The monochromator 120 may output a plurality of monochromatic lights by sweeping with a wavelength width/variant set in a certain wavelength range. The monochromator 120 may include a grating or a prism capable of splitting the incident light by wavelength.

The first collimator 130-1 may convert the monochromatic light incident from the monochromator 120 into a parallel light and output the parallel light. Meanwhile, the light may be transferred from the light source 110 to the monochromator 120 through a first optical fiber F1, and the light may be transferred from the monochromator 120 to the first collimator 130-1 through a second optical fiber F2. Transfer path of the light is not limited to the optical fiber.

The first polarizer 140-1 may polarize and output light from the first collimator 130-1. Polarization may be, for example, at least one of linear polarization, circular polarization, or elliptical polarization. Here, linear polarization may be converting an incident light into a linearly polarized light by passing only a p-polarized component (or a horizontal component) or an s-polarized component (or a vertical component) of the incident light. Circular polarization or elliptical polarization may be converting a linearly polarized light into a circularly polarized light or an elliptically polarized light by giving a phase difference to the linearly polarized light, or converting a circularly polarized light or an elliptically polarized light to another circularly polarized light or elliptically polarized light by giving a phase difference to the circularly polarized light or elliptically polarized light. In certain embodiments, a circularly polarized light or an elliptically polarized light may be converted into a linearly polarized light by giving a phase difference to the circularly polarized light or the elliptically polarized light. Accordingly, a polarizer performing circular polarization or elliptical polarization may be a phase retarder.

The beam splitter 150 may make light from the first polarizer 140-1 incident onto the substrate W, and emit reflected light reflected from the substrate W toward the first detector 190-1. For example, the beam splitter 150 may transmit or reflect light from the first polarizer 140-1 to make the light incident onto the substrate W, and reflect or transmit reflected light from the substrate W to emit the light toward the first detector 190-1.

The objective lens 160 may condense light from the beam splitter 150 onto the substrate W to make the light incident thereon. In addition, the objective lens 160 may make the reflected light reflected from the substrate W incident onto the beam splitter 150.

The first analyzer 170-1 may be disposed at a rear of (e.g., behind) the beam splitter 150 on an optical path of the imaging optical system, and may selectively pass the reflected light reflected from the substrate W and having a changed polarization direction. For example, the first analyzer 170-1 may pass only a specific polarization component among the incident light and block the other components. According to an embodiment, the first analyzer 170-1 may be disposed at a rear of (e.g., behind) the first imaging lens unit 180-1 on the optical path of the imaging optical system. Here, front and rear may be relative locations with respect to corresponding components in a direction in which light travels. For example, with regard to a lens, when light passes through the lens before being incident on a corresponding component, the lens may be regarded as being disposed in front of the corresponding component, and conversely, when light passes through (or reflected from) the corresponding component first and then passes through the lens, the lens is regarded as being disposed at the rear of the corresponding component.

The first imaging lens unit 180-1 may include at least one lens for imaging. For example, the first imaging lens unit 180-1 may include or may be an imaging tube lens. The first imaging lens unit 180-1 may make the light reflected from the substrate W incident onto the first detector 190-1 so that the substrate W is imaged on the first detector 190-1. The substrate W is not entirely imaged but only a part of the substrate W corresponding to a field of view (FOV) may be imaged on the first detector 190-1 through the first imaging lens unit 180-1. For example, the first detector 190-1 may take an image of a part of the substrate W at a time, and may take as much as images of the substrate W as needed, e.g., by multiple operations of the inspection device 100. In certain embodiments, the first detector 190-1 may take an image of the whole substrate W at a time, e.g., when the whole area of the substrate W is the same as or smaller than the FOV of the inspection device 100.

The first detector 190-1 may generate a 2D image of the substrate W. For example, the first detector 190-1 may receive the light reflected from the substrate W through the first imaging lens unit 180-1 so that the substrate W is imaged on an imaging surface. As described above, the 2D image of the substrate W is a 2D image formed on the first detector 190-1 corresponding to but the FOV not the entire substrate W. The first detector 190-1 may be, for example, a CCD camera. However, the first detector 190-1 is not limited to the CCD camera.

The first detector 190-1 may generate a plurality of 2D images of the substrate W corresponding to a plurality of wavelength bands. For example, in the inspection device 100 of the present embodiment, the light source 110 may generate and output a broadband light, and the monochromator 120 may split the broadband light into a plurality of wavelength bands and sequentially input the split lights into the substrate W. Accordingly, the first detector 190-1 may generate the plurality of 2D images of the substrate W corresponding to the wavelength bands. For example, the inspection device 100 may take multiple images of the same area of the substrate W which are taken by different wavelengths of light.

In the inspection device 100 of the present embodiment, the first detector 190-1 may be a detector having a high resolution. For example, the first detector 190-1 may have a pixel size of 500 nm or less and a FOV of 400*400 μm² or more. The pixel size and the FOV of the first detector 190-1 are not limited to the above numerical values. The first detector 190-1 may have a very high resolution due to its fine pixel size. For example, the first detector 190-1 may have a resolution of 500 nm or less.

In the inspection device 100 of the present embodiment, the first detector 190-1 is implemented with a high resolution based on the vertical optical system Vop, thereby contributing to miniaturization and high density of an inspection region in the substrate W, and accordingly, simultaneous measurement and/or measurement throughput of the substrate W may be improved. In addition, the first detector 190-1 may be considered to have a very small spot size or almost no spot size, and thus, a signal distortion caused by mismatching between the spot size and the size of a measurement area and a resulting reduction in a measurement consistency may be addressed.

The tilt optical system Top may include the light source 110, the monochromator 120, the second collimator 130-2, the second polarizer 140-2, the second analyzer 170-2, the second image lens unit 180-2, and a second detector 190-2. As described above, the light source 110 and the monochromator 120 may be shared the vertical optical system Vop and the tilt optical system Top, and have the same or substantially the same functions in the vertical optical system Vop and the tilt optical system Top. Therefore, detailed descriptions thereof are omitted.

The second collimator 130-2, the second polarizer 140-2, and the second analyzer 170-2 may be different from the first collimator 130-1, and the first polarizer 140-1, and the first analyzer 170-1 only in arrangement locations, and may perform the same or substantially the same functions as those of the first collimator 130-1 and the first polarizer 140-1, and the first analyzer 170-1, respectively. For example, as shown in FIG. 2, the second collimator 130-2 and the second polarizer 140-2 may be disposed on a path through which a monochromatic light output from the monochromator 120 is obliquely incident on the substrate W (e.g., in a tilted direction). The second analyzer 170-2 may be disposed on a path through which light reflected from the substrate W is obliquely output (e.g., in a tilted direction).

Here, the tilted direction may be a direction tilted with respect to an upper surface of the substrate W and/or a normal line of the upper surface. The second collimator 130-2 may convert the monochromatic light incident from the monochromator 120 into a parallel light and output the parallel light, the second polarizer 140-2 may polarize the parallel light coming from the second collimator 130-2 and output the polarized light to be incident on the substrate W, and the second analyzer 170-2 may selectively pass the reflected light reflected from the substrate W and having a changed polarization direction. For example, the polarized light incident on the substrate W and the reflected light reflected from the substrate W may have different polarization directions from each other.

The second imaging lens unit 180-2 may include at least one lens for imaging. For example, the second imaging lens unit 180-2 may include or may be an imaging tube lens. The second imaging lens unit 180-2 may cause the substrate W to be imaged on the second detector 190-2. The substrate W is not entirely imaged but only a part of the substrate W corresponding to a FOV may be imaged on the second detector 190-2 through the second imaging lens unit 180-2.

The second detector 190-2 may generate a 2D image of the substrate W. For example, the second detector 190-2 may receive the light reflected from the substrate W through the second imaging lens unit 180-2 so that the substrate W is imaged on an imaging surface. Like the first detector 190-1, the second detector 190-2 may generate a plurality of 2D images of the substrate W corresponding to a plurality of wavelength bands. The second detector 190-2 may also be a CCD camera. However, the second detector 190-2 is not limited to the CCD camera.

In the inspection device 100 of the present embodiment, the second detector 190-2 may be a high-resolution and large-area detector. For example, the second detector 190-2 may have a pixel size of 10 μm or less and a FOV of about 9*9 mm². Accordingly, the second detector 190-2 may have a high resolution and measure a part of the substrate W corresponding to a wide FOV in one imaging. For example, the second detector 190-2 may have a resolution of about 5 μm to about 10 μm and a FOV of 8*5 mm² to obtain the 2D image of the substrate W. Therefore, the second detector 190-2 may measure the substrate W in a plane unit (e.g., by unit areas) at high speed based on the wide FOV.

For example, when the resolution and the FOV of the first detector 190-1 are compared to those of the second detector 190-2, the resolution of the first detector 190-1 may be about 10 times greater than the resolution of the second detector 190-2. Also, the FOV of the second detector 190-2 may be about 100 times greater than the FOV of the first detector 190-1. Relative sizes of the resolution and FOV between the first detector 190-1 and the second detector 190-2 are not limited to the above numerical values.

In the inspection device 100 of the present embodiment, the second detector 190-2 is implemented to have a large-area FOV based on the tilt optical system Top, and thus, measurement areas included in the part of the substrate W corresponding to the FOV may be simultaneously measured at one time. Accordingly, a measurement speed with respect to the measurement areas of the substrate W may be significantly improved.

The substrate W may be disposed on the stage 155. The stage 155 may move the substrate W through a linear movement in x, y, and z directions. Accordingly, the stage 155 is also referred to as an x-y-z stage. According to an embodiment, the stage 155 may move the substrate W through a linear and/or rotational movement.

Here, the substrate W may be various devices to be inspected, such as a wafer, a semiconductor package, a semiconductor chip, and a display panel. For example, in the inspection device 100 of the present embodiment, the substrate W may be a wafer including a plurality of semiconductor chips. In addition, a plurality of measurement areas for a lithography process control may be formed on a wafer, which is the substrate W. For example, the plurality of measurement areas may include an overlay key, a focus key, a dose key, a CD key, etc.

Although not shown, each of the vertical optical system Vop and the tilt optical system Top may further include optical elements in addition to the above-described components. For example, in the case of the vertical optical system Vop, an illumination optical system portion may further include a shutter, a neutral density (ND) filter, one or more reflection mirrors, a focus lens, etc. In addition, in the tilt optical system Top, an illumination optical system portion may include a shutter and an ND filter in, and an illumination optical system portion may include one or more folding mirrors.

The inspection device 100 according to the present embodiment may include the high-resolution SMI mode vertical optical system Vop and the large-area SMI mode tilt optical system Top. Accordingly, the inspection device 100 of the present embodiment may contribute to miniaturization and densification of the measurement areas in the substrate W based on the vertical optical system Vop, and also improve simultaneous measurement and/or measurement throughput of the measurement areas.

The inspection device 100 of the present embodiment may measure the substrate W with the large-area FOV at high resolution based on the tilt optical system Top, thereby measuring the substrate W at high speed in a unit of plane (e.g., by unit areas). The inspection device 100 of the present embodiment may measure measurement areas in a scribe lane, for example, not only an overlay key but also overlays between patterns in cells, thereby obtaining an overlay locality in a shot according to a process variation and also, securing accurate data by removing noise due to an average effect.

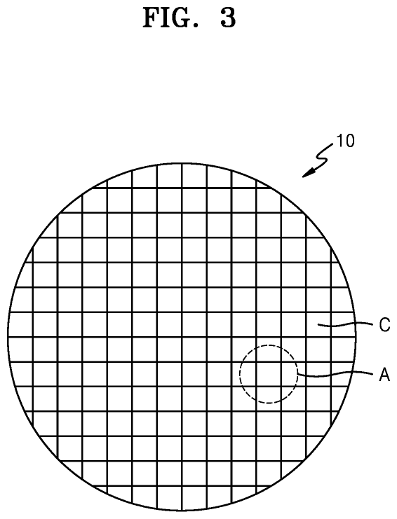

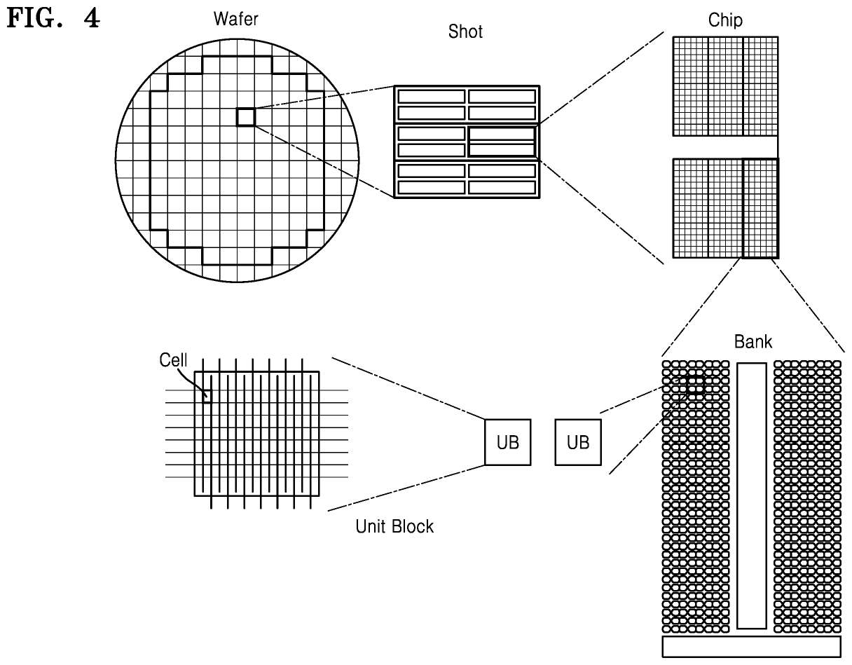

FIGS. 3 and 4 are diagrams illustrating a measurement area on a substrate by the optical device 100 of FIG. 2 according to an embodiment.

FIG. 3 shows a substrate 10 as an example of an object to be inspected in the optical device 100 of FIG. 2. Referring to FIG. 3, the substrate W is a wafer including a plurality of chips C, and an inspection area A that is an inspection target may include the one or more chips C. Alternatively, the inspection area A may be an area corresponding to the single chip (C). The substrate W may be a wafer.

FIG. 4 is a diagram illustrating the inspection area A on the substrate 10 in units of a wafer, a shot, a chip, a bank, a unit block, and a cell. Referring to FIG. 4, a wafer which is the inspection area A is shown at the top left and includes multiple shots divided by straight lines therein. Here, a shot may mean a process of transferring patterns on a mask onto a wafer through one exposure in a lithography process or an area on the wafer corresponding thereto.

A shot is enlarged in the second from the top left. One shot may include multiple chips. For example, eighteen chips may be included in one shot. However, the number of chips included in a shot is not limited to eighteen. For example, depending on the type of a chip, a shot may include one chip or multiple chips.

A chip is enlarged in the third from the top left. One chip, e.g., a memory chip such as DRAM, may have a structure in which multiple banks are arranged on both sides of a scribe lane in the center thereof.

A bank is enlarged at the bottom right and may be an aggregate of multiple unit blocks. A scribe lane may also exist between banks. For reference, a scribe lane usually means an area for sawing, but may mean an area other than a bank portion where cells are arranged. A unit block is enlarged at the bottom left, and may be an aggregate (e.g., a group) of cells.

Here, the optical device 100 may perform a substrate inspection by covering/inspecting the inspection area A in units of a whole wafer, a shot, a chip, and a block. For example, the tilt optical system Top of the optical device 100 may obtain a spectrum in units of blocks in a large-area SMI mode. In certain embodiments, the tilt optical system Top of the optical device 100 may obtain a spectrum of a substrate in units of any one of a whole wafer, a shot, and a chip. In the following description, a block may refer to a block unit.

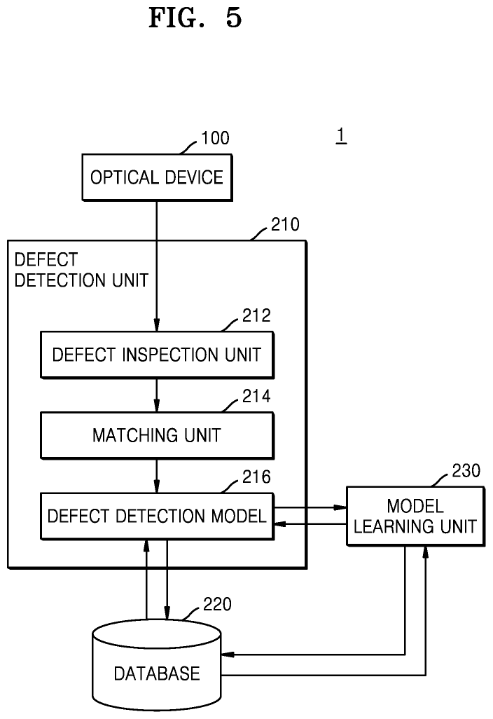

FIG. 5 is a block diagram illustrating the defect detection device 1 according to an embodiment. In describing the embodiment illustrated in FIG. 5 below, FIGS. 1 to 4 are referenced together, and descriptions already given with reference to FIGS. 1 to 4 are briefly described or omitted.

Referring to FIG. 5, the defect detection device 1 may include the optical device 100, a defect detection unit 210, a database 220 and a model learning unit 230. The defect detection unit 210 may include a defect inspection unit 212, a matching unit 214 and a defect detection model 216. Here, the defect detection unit 210 may correspond to the server 40 of FIG. 1. For example, the server 40 of FIG. 1 may include the defect inspection unit 212, the matching unit 214 and the defect detection model 216. The optical device 100 may radiate light to a substrate to respectively obtain a plurality of spectrum images of each of a plurality of blocks in the substrate.

The optical device 100 may generate spectrum data of one chip of the substrate. The spectrum data of the one chip may include or be formed of spectrum date of the plurality of blocks in the one chip. Also, the optical device 100 may obtain the plurality of spectrum images of each of the plurality of blocks in the substrate based on (e.g., using) layout information and address information of the chip of the spectrum data. Here, the layout information of the chip may be information about a layout (e.g., position, shape, size, etc.) of the chip in the substrate, and the address information may be information about a location of each of the plurality of blocks in the chip. The optical device 100 may obtain a spectrum image by using light of a short wavelength, a medium wavelength, and a long wavelength. For example, the optical device 100 may obtain the plurality of spectrum images by using light having a wavelength of about 270 mm to about 750 mm.

The defect inspection unit 212 may perform an electrical die sorting (EDS) test on the substrate. Also, the defect inspection unit 212 may inspect defects of each of the plurality of blocks of the substrate based on a result of the EDS test. The model learning unit 230 may receive the spectrum image and defect information from the database 220. The defect detection unit 210 may extract a feature vector from a target spectrum image obtained from the optical device 100 by using the defect detection model 216. The defect detection unit 210 may detect a target defect grade of the target spectrum image based on the feature vector. In the present disclosure, a feature vector may be a feature related to a defect of pattern (e.g., a feature shown in an image) or related to a function of a chip (or an element in a chip). For example, a feature vector may be a distinguishable image shown in a spectrum image or a malfunction of an element, a device, a block or a chip. For example, the feature vector may be a tendency of defect, a defect (e.g., a featured defect itself), a defect pattern, or a defect image.

The defect inspection unit 212 may perform the EDS test on the substrate. Also, the defect inspection unit 212 may inspect defects of each of the plurality of blocks of the substrate based on the result of the EDS test. In this regard, defects of each of the plurality of blocks may include various types of defects. The defect inspection unit 212 may classify defects of each of the plurality of blocks and select a target defect that is an inspection target. For example, the defect inspection unit 212 may receive any one of a plurality of defects including various defects as the target defect and store defect information about the target defect in the database 220. In this case, the defect information may include location information of each of the plurality of blocks, information about the number of defects, etc. The defect inspection unit 212 may perform the EDS test on the chip of the substrate, and classify types of defects of each of the plurality of blocks based on an electrical signal of the chip. The defect inspection unit 212 may classify types of defects based on the duration, voltage, or current of the electrical signal.

The matching unit 214 may match the plurality of spectrum images and the defect information of each of the plurality of blocks. Because the plurality of spectrum images are images of the plurality of blocks, the matching unit 214 may match the spectrum image of one block and the defect information corresponding to the one block in 1:1 (one on one) matching. The matching unit 214 may match the plurality of spectrum images and the defect information with respect to each of the plurality of blocks and store the plurality of spectrum images and the defect information in the database 220.

The defect detection model 216 may generate a defect grade of each of a plurality of target blocks of the target spectrum image with respect to the substrate that is an inspection target. The defect detection method by the defect detection device may be performed by an electronic device itself, or may be performed through the separate server 40 of FIG. 1. A learning algorithm may include, for example, supervised learning, but is not limited to the above example. The defect detection model 216 may include a plurality of artificial neural network layers. Artificial neural networks may include deep neural networks (DNNs), convolutional neural networks (CNNs), recurrent neural networks (RNNs), restricted Boltzmann machines (RBMs), deep belief networks (DBNs), bidirectional recurrent deep neural networks (BRDNNs), deep Q-networks or a combination of two or more thereof but are not limited thereto.

A database 220 may have a general data structure implemented in a storage space (e.g., a hard disk or a memory) of a computer system using a database management program/system (DBMS). The database 220 may have a data storage form (e.g., an electronic storage) in which data may be freely searched for, deleted, edited, added, etc. The database 220 may be implemented according to the purpose of an embodiment using a relational database management system (RDBMS), such as Oracle, Informix, Sybase, and DB2, an object-oriented database management system (OODBMS), such as Gemston, Orion, and O2, or an XML-only DB (XML native DB), such as Excelon, Tamino, and Sekaiju, and may have appropriate fields or elements to achieve a function thereof. Also, the database 220 may receive data from a user interface (not shown). In addition, the database 220 may transmit and receive data with the optical device 100, the defect inspection unit 212, the matching unit 214, the defect detection model 216, and the model learning unit 230.

The model learning unit 230 may train the defect detection model 216. For example, the model learning unit 230 may train the defect detection model 216 by using the defect grade as an output value and the spectrum image and the defect information received from the database 220 as input values.

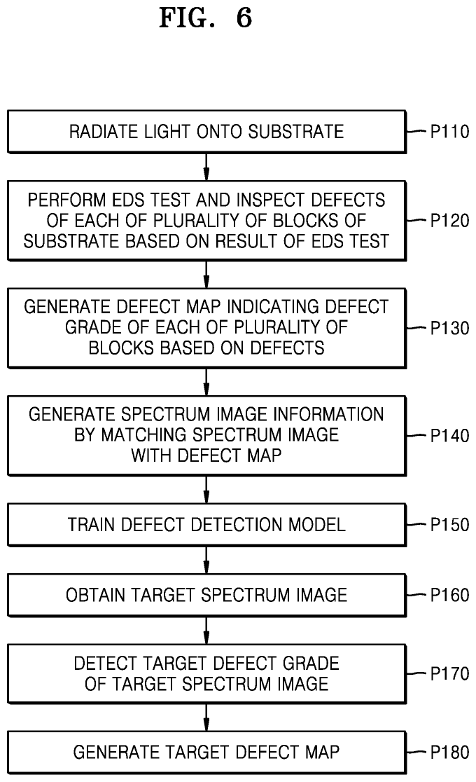

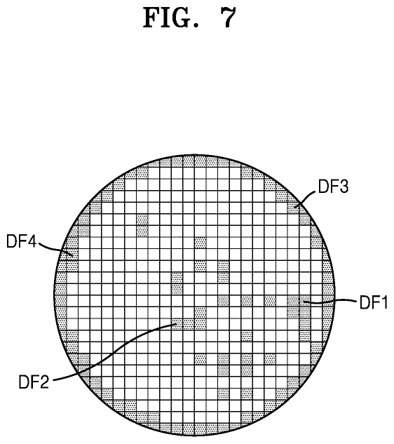

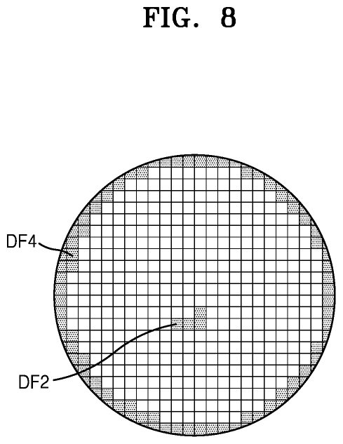

FIG. 6 is a flowchart illustrating a defect detection method according to an embodiment. FIGS. 7 and 8 are defect maps illustrating a defect detection method according to an embodiment.

Referring to FIG. 6, the defect detection method of the embodiment of the inventive concept may include radiating light onto a substrate, and obtaining a spectrum image indicating an amount of the light according to a wavelength from reflected light reflected from the substrate (P110). The spectrum image may include an image of one chip in the substrate. For example, operation P110 of obtaining the spectrum image may include generating the spectrum image in units of any one or more of a whole substrate, a shot, a chip, and a block, and extracting the spectrum image of each of a plurality of blocks based on chip layout information of the substrate and location information of each of the plurality of blocks of the substrate. For example, the spectrum image may be generated in units of the chip of the substrate, and then an individual spectrum image of each of the plurality of blocks may be obtained based on the chip layout information and the location information.

Next, an EDS test may be performed on the substrate, and defects of each of the plurality of blocks of the substrate may be inspected based on a result of the EDS test (P120). Here, operation P120 of inspecting defects of each of the plurality of blocks may include classifying types of defects of each of the plurality of blocks of the substrate based on the result of the EDS test, and selecting a target defect that is an inspection target based on the classified types of defects. In some embodiments, an operation of selecting the target defect that is the inspection target may include removing the remaining defects except for the target defect. However, the inventive concept is not limited thereto, and a defect map may be generated and then data or information about the remaining defects may be removed.

Referring to FIGS. 6, 7, and 8, the defect map indicating a defect grade of each of the plurality of blocks may be generated based on the defects (P130). Here, defect information including the defect grade as well as the defect map indicating the defect grade may be generated, and defect information may be stored in the database 220 of FIG. 5. Operation S130 of generating the defect map may include generating a defect map of the target defect.

In addition, a comprehensive map including the target defect and the remaining defects may be generated, and then the defect map of the target defect may be generated. For example, as shown in FIG. 7, the comprehensive map including different defects DF1, DF2, DF3, and DF4 may be generated. Next, as shown in FIG. 8, a defect map from which the remaining defects except for the target defect are deleted may be generated. When a block includes a defect, the defect may be displayed in the comprehensive map or the defect map in gray as shown in FIGS. 7 and 8. The inventive concept is not limited thereto, and the defect may be displayed in another color.

Spectrum image information including the spectrum image and the defect information corresponding to the spectrum image may be generated by matching the spectrum image and the defect map (P140). The spectrum image information may be information obtained by matching the spectrum images and the defect information with respect to each of the plurality of blocks.

A defect detection model may be trained by using the defect grade as an output value and the spectrum image information as an input value (P150). Next, a target spectrum image may be obtained from an optical device (P160). The target spectrum image may be a spectrum image of a substrate (e.g., a target substrate) or a chip (e.g., a target chip) that is different from the spectrum image used in step P150.

A feature vector may be extracted from the target spectrum image by using a defect detection model, and a target tendency grade of the target spectrum image may be detected based on the feature vector (P170). A target defect map may be generated based on the target defect grade (P180). The target defect map may be the same as or similar to the comprehensive map and/or the defect map described above.

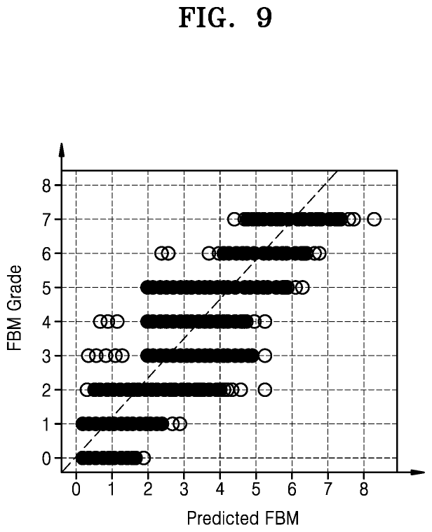

FIG. 9 is a graph illustrating effects of a defect detection device and a defect detection method according to an embodiment.

Referring to FIG. 9, a horizontal axis represents a defect grade predicted with respect to a target defect of a substrate by the defect detection device and the defect detection method, and a vertical axis represents a defect grade according to an EDS test of the substrate. As shown in FIG. 9, the predicted defect grade generally tends to identical with the defect grade according to the EDS test. For example, the defect detection devices and the defect detection methods of the embodiments of the inventive concept may detect defects in a pattern of the substrate during a semiconductor manufacturing process. Through this, defects in the pattern are found before the process is completed, and thus, the stability and reliability of a semiconductor device may be improved.

According to another embodiment of the present disclosure, a method of manufacturing a semiconductor device includes steps of preparing a substrate. The substrate may be prepared by forming various conductive patterns, various insulating layers and a plurality of semiconductor patterns on a base substrate (e.g., a base substrate formed of or including a semiconductor material). The substrate may be inspected by any defect detection method and/or using any defect detection device disclosed in the present disclosure to determine a fair quality or a defect of a chip/block of the substrate and/or to determine whether to repair the defect. After the substrate is inspected, a defect may be repaired and/or the substrate may be diced into chips and may be packaged in a following process to form semiconductor chips and/or semiconductor packages.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A defect detection method comprising:
radiating light onto a substrate;
obtaining a spectrum image indicating an amount of the light according to a wavelength from reflected light reflected from the substrate;
performing an electrical die sorting (EDS) test on the substrate;
inspecting defects of each of a plurality of blocks of the substrate based on a result of the EDS test;
generating a defect map indicating a defect grade of each of the plurality of blocks based on the defects;
generating spectrum image information comprising the spectrum image and defect information corresponding to the spectrum image by matching the spectrum image with the defect map;
training a defect detection model by using the defect grade as an output value and the spectrum image information as an input value;
obtaining a target spectrum image with respect to a target substrate;
extracting a feature vector from the target spectrum image by using the defect detection model, and detecting a target defect grade of the target spectrum image based on the feature vector; and
generating a target defect map based on the target defect grade.

2. The defect detection method of claim 1, wherein the obtaining of the spectrum image includes:
generating the spectrum image in units of one or more of a whole substrate, a shot, a chip, and a block; and
extracting the spectrum image of each of the plurality of blocks based on chip layout information of the substrate and location information of each of the plurality of blocks of the substrate.

3. The defect detection method of claim 1, wherein the inspecting of the defects includes:
classifying types of the defects of each of the plurality of blocks of the substrate based on a result of the EDS test; and
selecting a target defect that is an inspection target based on the classified types of the defects, and
wherein the generating of the defect map includes generating the defect map of the target defect.

4. The defect detection method of claim 3, wherein the inspecting of the defects includes classifying the types of the defects of each of the plurality of blocks based on an electrical signal of a chip of the substrate.

5. The defect detection method of claim 1, wherein the generating of the spectrum image information includes matching an image corresponding to each of the plurality of blocks in the spectrum image with the defect grade of each of the plurality of blocks of the defect map.

6. The defect detection method of claim 1, wherein the spectrum image is obtained by spectral reflectometry.

7. The defect detection method of claim 1, further comprising:
performing the EDS test on a target substrate of the target spectrum image;
determining consistency of the target defect grade by comparing the target defect grade with the result of the EDS test; and
training the defect detection model again based on the consistency of the target defect grade.

8. The defect detection method of claim 1, wherein the defect detection model is based on at least one of a deep neural network (DNN), a convolutional neural network (CNN), or a recurrent neural network (RNN).

9. The defect detection method of claim 1, wherein the defect map and the target defect map are maps in which a target defect that is an inspection target is marked on each of the plurality of blocks in the substrate.

10. A defect detection device comprising:
an optical device configured to radiate light onto a substrate and obtain a plurality of spectrum images of each of a plurality of blocks in the substrate;
a defect inspection unit configured to perform an electrical die sorting (EDS) test on the substrate and inspect defects of each of the plurality of blocks of the substrate based on a result of the EDS test;
a matching unit configured to match the plurality of spectrum images with defect information of each of the plurality of blocks;
a database storing the plurality of matched spectrum images and the defect information corresponding to the plurality of spectrum images;
a model learning unit configured to train a defect detection model by using a defect grade as an output value and the plurality of spectrum images and the defect information received from the database as input values; and
a defect detection unit configured to extract a feature vector from a target spectrum image obtained from the optical device by using the defect detection model and detect a target defect grade of the target spectrum image based on the feature vector.

11. The defect detection device of claim 10, wherein the optical device is further configured to generate spectrum data of one chip of the substrate and obtain the plurality of spectrum images of each of the plurality of blocks in the substrate based on layout information and address information of the chip of the spectrum data.

12. The defect detection device of claim 10, wherein the defect inspection unit is further configured to classify the defects of each of the plurality of blocks and select a target defect that is an inspection target.

13. The defect detection device of claim 10, wherein the optical device is further configured to obtain the plurality of spectrum images of each of the plurality of blocks in the substrate by using spectral reflectometry.

14. The defect detection device of claim 10, wherein the defect detection model is based on at least one of a deep neural network (DNN), a convolution neural network (CNN), or a recurrent neural network (RNN).

15. The defect detection device of claim 10, wherein the optical device is further configured to obtain the plurality of spectrum images by using light having a wavelength of about 270 nm to about 750 nm.

16. The defect detection device of claim 10, wherein the defect detection model is configured to generate a defect grade of each of a plurality of target blocks of the target spectrum image.

17. The defect detection device of claim 10, wherein the defect inspection unit is further configured to perform the EDS test on a chip of the substrate and classify types of the defects of each of the plurality of blocks based on an electrical signal of the chip.

18. A defect detection method comprising:
radiating light onto a substrate;
generating a spectrum image in units of any one or more of a whole substrate, a shot, a chip, and a block from reflected light reflected from the substrate;
extracting a spectrum image of each of a plurality of blocks based on chip layout information of the substrate and location information of each of the plurality of blocks of the substrate;
performing an electrical die sorting (EDS) test on the substrate;
inspecting defects of each of the plurality of blocks of the substrate based on a result of the EDS test;
generating a defect map indicating a defect grade of each of the plurality of blocks based on the defects;
generating spectrum image information comprising the spectrum image and defect information corresponding to the spectrum image by matching the spectrum image with the defect map;
training a defect detection model by using the defect grade as an output value and the spectrum image information as an input value;
obtaining a target spectrum image from an optical device;
extracting a feature vector from the target spectrum image by using the defect detection model, and detecting a target defect grade of the target spectrum image based on the feature vector; and
generating a target defect map based on the target defect grade,
wherein the inspecting of the defects comprises:
classifying types of the defects of each of the plurality of blocks of the substrate based on a result of the EDS test; and
selecting a target defect that is an inspection target based on the classified types of the defects.

19. The defect detection method of claim 18, wherein
the defect detection model is based on at least one of a deep neural network (DNN), a convolutional neural network (CNN), or a recurrent neural network (RNN), and
the defect map and the target defect map are maps in which a target defect that is an inspection target is marked on each of the plurality of blocks in the substrate.

20. The defect detection method of claim 18, wherein the light radiated onto the substrate is light having a wavelength of about 270 nm to about 750 nm.
